(19) United States
(12) Patent Application Publication
(10) Pub. No.: US 2026/0087214 A1
(43) Pub. Date: Mar. 26, 2026

(54) INTEGRATED CIRCUIT DESIGN WITH ON-DEMAND ENABLED LAYER

(71) Applicant: SiFive, Inc., Santa Clara, CA (US)

(72) Inventor: Schuyler Eldridge, New York, NY (US)

(73) Assignee: SiFive, Inc., Santa Clara, CA (US)

(21) Appl. No.: 18/895,258

(22) Filed: Sep. 24, 2024

(51) Int. Cl. G06F 30/31

(52) U.S. Cl. CPC G06F 30/31

(57) ABSTRACT

The present application relates to generating a design for an integrated circuit, where the design includes a layer that can be enabled and/or disabled on demand. In an example, a system receives an input declaring a layer associated with a function. The system defines a first layer block of the layer, where corresponding code references the layer and is included in code of a first module. The system defines a second layer block of the layer, where corresponding code references the layer and is included in code of a second module. The system defines a first port for the first layer block, the first port referencing the layer and indicating that output of the first layer block is accessible to the second layer block conditioned on the layer being enabled. The system causes a compilation of the codes, where the compilation removes the first port from the circuit design.

### BACKGROUND

An integrated circuit generator can enable designing integrated circuits. In an example, the integrated circuit generator uses a hardware description language (HDL) and receives inputs describing aspects related to an integrated circuit. HDL-based code can be generated based on the inputs. A circuit design for the integrated circuit can be generated from the HDL-based code.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 illustrates an example of a system for facilitating generation and manufacture of integrated circuits in accordance with embodiments of the present disclosure.

FIG. 2 illustrates an example of computing components of a system for facilitating generation of integrated circuits in accordance with embodiments of the present disclosure.

FIG. 3 illustrates an example of components of an integrated circuit design with a layer defined in a hardware description language (HDL) in accordance with embodiments of the present disclosure.

FIG. 4 illustrates an example of components of an integrated circuit design with a layer defined in a register-transfer level (RTL) data structure in accordance with embodiments of the present disclosure.

FIG. 5 illustrates another example of components of an integrated circuit design with nested layers defined in an HDL and an RTL data structure in accordance with embodiments of the present disclosure.

FIG. 6 illustrates an example of data flow between components of an integrated circuit design defined in an HDL in accordance with embodiments of the present disclosure.

FIG. 7 illustrates an example of data flow between components of an integrated circuit design defined in an RTL data structure in accordance with embodiments of the present disclosure.

FIG. 8 illustrates an example of a flow for generating an integrated circuit design with one or more layers in accordance with embodiments of the present disclosure.

### DETAILED DESCRIPTION

Embodiments of the present disclosure relate to, among other things, generating a design for an integrated circuit, where the design includes one or more layers that can be enabled and/or disabled on demand (e.g., upon user input). The integrated circuit can include different hardware components, such as memories, processors, and the like. The design can include software modules, each corresponding to (e.g., defining) one or more of the hardware components. A layer can provide a particular function related to the design (e.g., to verify, validate, and/or debug the design, check and/or monitor software execution of the design, collect data related to the execution, etc.). User input can enable a layer, whereby the function of the layer can be performed on the design (e.g., the software modules). Conversely, user input can disable the layer such that the function is not performed on the design. In both cases, the layer need not be implemented in hardware (e.g., included as a hardware component of the integrated circuit).

In an example, the design can be initially defined a hardware description language (HDL) and subsequently compiled into a register-transfer level (RTL) data structure. The HDL design can describe the software modules (referred to herein as “modules” for brevity) corresponding to the hardware component(s) of the integrated circuit. The HDL design can also define a layer for a function (e.g., a verification), whereby a layer block can be included in a software module and can correspond to certain aspects of the layer's function (e.g., to collect and aggregate data used in the verification). For instance, code (e.g., software code) of the layer block can be included in code of the module. Furthermore, the layer block and/or the module can include a port that references the layer, whereby the port represents a data flow that enables the output of the layer block to be used by another layer block of the layer and/or the layer block to receive an output of the other layer block. This other layer block can be included in another module, where this module may, but need not, correspond to hardware component(s) of the integrated circuit. The function of a port (e.g., enable a data flow) can be referred to herein as “coloring” to indicate that the data flow between layer blocks are “colored.”

Given the layer definition (including the layer blocks and port(s)), a compiler can generate the RTL data structure. Here, each HDL module can be compiled into an RTL module. Each layer block can be compiled into an RTL module separate from the other RTL modules. A port need not be included in the RTL data structure and can be replaced in an RTL module with a reference associated with the layer (e.g., a hierarchical name to another RTL software module).

In this way, the HDL code can define, in addition to a design of an integrated circuit, a layer for a function to be performed on the design. The RTL data structure can define modules for the design (design modules) and modules for the layer (layer modules), where the design modules are separate from the layer modules, and where the design modules do not include ports specific to the layer. Instead, the layer modules can be enabled and/or disabled on-demand (e.g., by being instantiated and/or terminated in the design modules), without the need to change (e.g., add/remove ports) the design modules. In this way, the function can be performed on-demand using the RTL data structure (e.g., by enabling/disabling the layer in RTL) without necessitating a change to the integrated circuit design (e.g., the RTL design modules). Further, the hardware components can be produced without having to include hardware components for the layer (and without the need to change the integrated circuit design).

In an example, an integrated circuit is an application specific integrated circuit (ASIC) or a system on a chip (SoC). Automated generation of the integrated circuit design permits a configuration to be specified in terms of design parameters (or colloquially knobs). A system may then automate the operation of commercial electronic design automation (EDA) tools for design of the integrated circuit using the design parameters. For instance, the system may execute an integrated circuit generator to access design parameters and generate an integrated circuit design. The integrated circuit generator may use an HDL embedded in a general-purpose programming language (e.g., Scala) that supports object-oriented programming and/or functional programming. For example, Chisel may be used to generate an integrated circuit design. Chisel is an open source HDL embedded in Scala, a statically typed general purpose programming language that supports both object-oriented programming and functional programming. The integrated circuit generator may include module descriptions that specify input(s), output(s), and/or a description(s) of a functional operation of a module (e.g., a processor core, cache, or the like, which may be represented, for example, by a Scala class).

In a process referred to as elaboration, the integrated circuit generator may execute to generate an integrated circuit design based on the design parameters. The integrated circuit design may include instances of module descriptions with connections being made. For example, the integrated circuit generator may execute constructor code to establish instances of Scala classes, with wired connections between them, as an instantiation of an integrated circuit design. In an example, the integrated circuit design may be encoded in an intermediate representation (IR) data structure. The IR data structure may be configured for optimization and/or translation by a compiler to produce an RTL data structure. For example, the integrated circuit generator may generate the integrated circuit design as a flexible intermediate representation for register-transfer level (FIRRTL) data structure. The FIRRTL data structure may be compiled by a FIRRTL compiler to produce an RTL data structure.

In a process referred to as compilation, the elaborated integrated circuit design (e.g., the IR data structure) may be compiled to generate an RTL data structure. For example, compiling the integrated circuit design may comprise executing one or more lowering transformations (e.g., compiler transformations that remove high-level constructs) to transform the integrated circuit design to generate the RTL data structure. The RTL data structure may encode a topology of logic associated with the instances of module descriptions implemented in the integrated circuit design (e.g., logic descriptions of the modules, such as the processor cores, caches, and the like). The RTL data structure may be compatible with EDA tools that may be used for functional verification (e.g., simulation analysis), synthesis (e.g., conversion to a gate-level description), placement and routing (e.g., physical design), and/or manufacturing of an integrated circuit (e.g., a processor, a microcontroller, an ASIC, or an SoC). In an example, the RTL data structure may comprise Verilog. For example, the integrated circuit design may be compiled using a FIRRTL compiler to generate Verilog.

The integrated circuit generator and/or a compiler may use Scala or Chisel to generate an integrated circuit design including an object model in a standardized data structure (e.g., a java script object notation (JSON), metadata, etc.). Through use of classes of Chisel or Scala, which can define properties (e.g., data members) and behaviors (e.g., methods) that objects of that class can possess, design codes can be reused through use of libraries that implement an abstract solution and be instantiated with many different data types.

Moreover, the integrated circuit generator and/or a compiler may use Scala or Chisel to generate an integrated circuit design instances of module descriptions. A module description may specify input(s), output(s), and/or a description(s) of a functional operation of a module (e.g., a processing component such as arithmetic logic units, multiplexers, and/or any other component that can belong to a processor core; a state element such as a register or any other component that can store data; a protection component, such as an encoder and/or decoder, possibly implementing a particular protection technique such as single error correction double error detection (SECDED) or parity bits-based protection; etc. all of which may be represented, for example, by a corresponding Scala class). Instances of module descriptions may include input(s) and/or output(s) (e.g., wires) that may be internal to the integrated circuit design (e.g., as opposed to a system level input(s) and/or output(s) that may be external to the integrated circuit design). The generator (e.g., Chisel) may use an HDL embedded in a general-purpose programming language (e.g., Scala) to generate the integrated circuit design. The integrated circuit design may be encoded in an IR data structure. A compiler (e.g., a FIRRTL compiler) may compile the IR data structure to produce an RTL data structure. The RTL data structure may encode logic descriptions associated with the instances of module descriptions implemented in the integrated circuit design (e.g., Verilog).

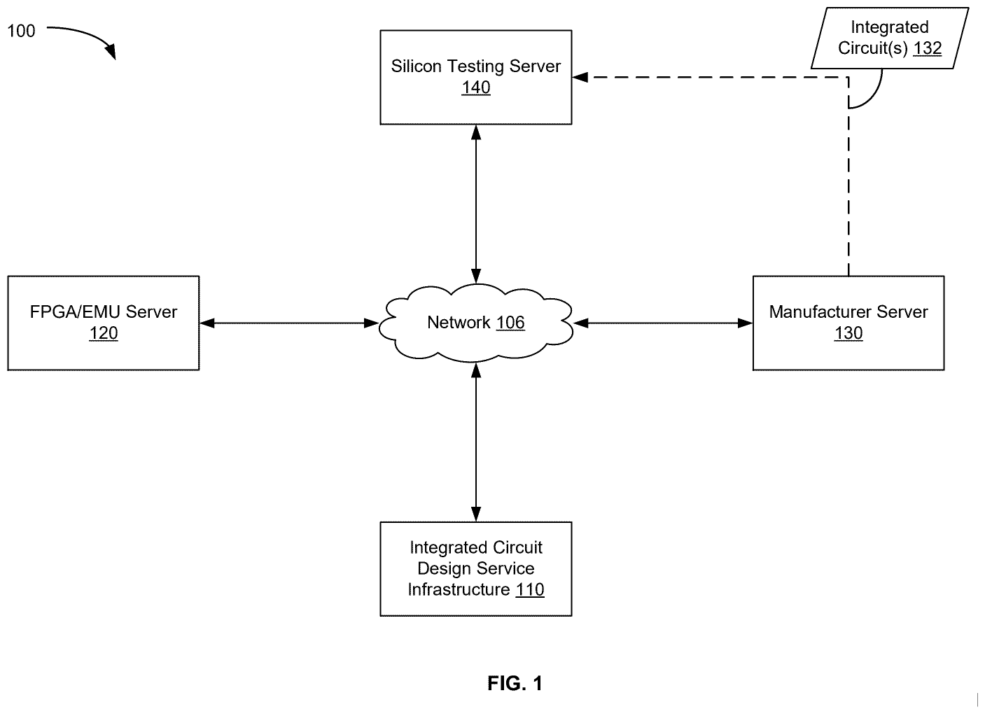

FIG. 1 illustrates an example of a system 100 for facilitating generation and manufacture of integrated circuits in accordance with embodiments of the present disclosure. The system 100 includes a network 106, an integrated circuit design service infrastructure 110 (e.g., integrated circuit generator), a field programmable gate array (FPGA)/emulator server 120, and a manufacturer server 130. For example, a user may utilize a web client or a scripting API client to command the integrated circuit design service infrastructure 110 to automatically generate an integrated circuit design based on a set of design parameter values selected by the user for one or more template integrated circuit designs. In an example, the integrated circuit design service infrastructure 110 may be configured to generate an integrated circuit design like the integrated circuit design shown in some of the next figures.

The integrated circuit design service infrastructure 110 may include a an RTL service module configured to generate an RTL data structure for the integrated circuit based on a design parameters data structure. For example, the RTL service module may be implemented as Scala code. For example, the RTL service module may be implemented using Chisel. For example, the RTL service module may be implemented using FIRRLT and/or a FIRRTL compiler. For example, the RTL service module may enable a well-designed chip to be automatically developed from a high-level set of configuration settings using a mix of Diplomacy, Chisel, and FIRRTL. The RTL service module may take the design parameters data structure (e.g., JSON file) as input and output an RTL data structure (e.g., a Verilog file) for the chip.

In an example, the integrated circuit design service infrastructure 110 may invoke (e.g., via network communications over the network 106) testing of the resulting design that is performed by the FPGA/emulation server 120 that is running one or more FPGAs or other types of hardware or software emulators. For example, the integrated circuit design service infrastructure 110 may invoke a test using a field programmable gate array, programmed based on a field programmable gate array emulation data structure, to obtain an emulation result. The field programmable gate array may be operating on the FPGA/emulation server 120, which may be a cloud server. Test results may be returned by the FPGA/emulation server 120 to the integrated circuit design service infrastructure 110 and relayed in a useful format to the user (e.g., via a web client or a scripting API client).

The integrated circuit design service infrastructure 110 may also facilitate the manufacture of integrated circuits using the integrated circuit design in a manufacturing facility associated with the manufacturer server 130. In an example, a physical design specification (e.g., a graphic data system (GDS) file, such as a GDSII file) based on a physical design data structure for the integrated circuit (e.g., an RTL data structure) is transmitted to the manufacturer server 130 to invoke manufacturing of the integrated circuit (e.g., using manufacturing equipment of the associated manufacturer). For example, the manufacturer server 130 may host a foundry tape-out website that is configured to receive physical design specifications (e.g., such as a GDSII file or an open artwork system interchange standard (OASIS) file) to schedule or otherwise facilitate fabrication of integrated circuits. In an example, the integrated circuit design service infrastructure 110 supports multi-tenancy to allow multiple integrated circuit designs (e.g., from one or more users) to share fixed costs of manufacturing (e.g., reticle/mask generation, and/or shuttles wafer tests). For example, the integrated circuit design service infrastructure 110 may use a fixed package (e.g., a quasi-standardized packaging) that is defined to reduce fixed costs and facilitate sharing of reticle/mask, wafer test, and other fixed manufacturing costs. For example, the physical design specification may include one or more physical designs from one or more respective physical design data structures in order to facilitate multi-tenancy manufacturing.

In response to the transmission of the physical design specification, the manufacturer associated with the manufacturer server 130 may fabricate and/or test integrated circuits based on the integrated circuit design. For example, the associated manufacturer (e.g., a foundry) may perform optical proximity correction (OPC) and similar post-tape-out/pre-production processing, fabricate the integrated circuit(s) 132, update the integrated circuit design service infrastructure 110 (e.g., via communications with a controller or a web application server) periodically or asynchronously on the status of the manufacturing process, perform appropriate testing (e.g., wafer testing), and send to a packaging house for packaging. A packaging house may receive the finished wafers or dice from the manufacturer and test materials and update the integrated circuit design service infrastructure 110 on the status of the packaging and delivery process periodically or asynchronously. In an example, status updates may be relayed to the user when the user checks in using the web interface, and/or the controller might email the user that updates are available.

In an example, the resulting integrated circuit(s) 132 (e.g., physical chips) are delivered (e.g., via mail) to a silicon testing service provider associated with a silicon testing server 140. In an example, the resulting integrated circuit(s) 132 (e.g., physical chips) are installed in a system controlled by the silicon testing server 140 (e.g., a cloud server), making them quickly accessible to be run and tested remotely using network communications to control the operation of the integrated circuit(s) 132. For example, a login to the silicon testing server 140 controlling a manufactured integrated circuit(s) 132 may be sent to the integrated circuit design service infrastructure 110 and relayed to a user (e.g., via a web client). For example, the integrated circuit design service infrastructure 110 may be used to control testing of one or more integrated circuit(s) 132.

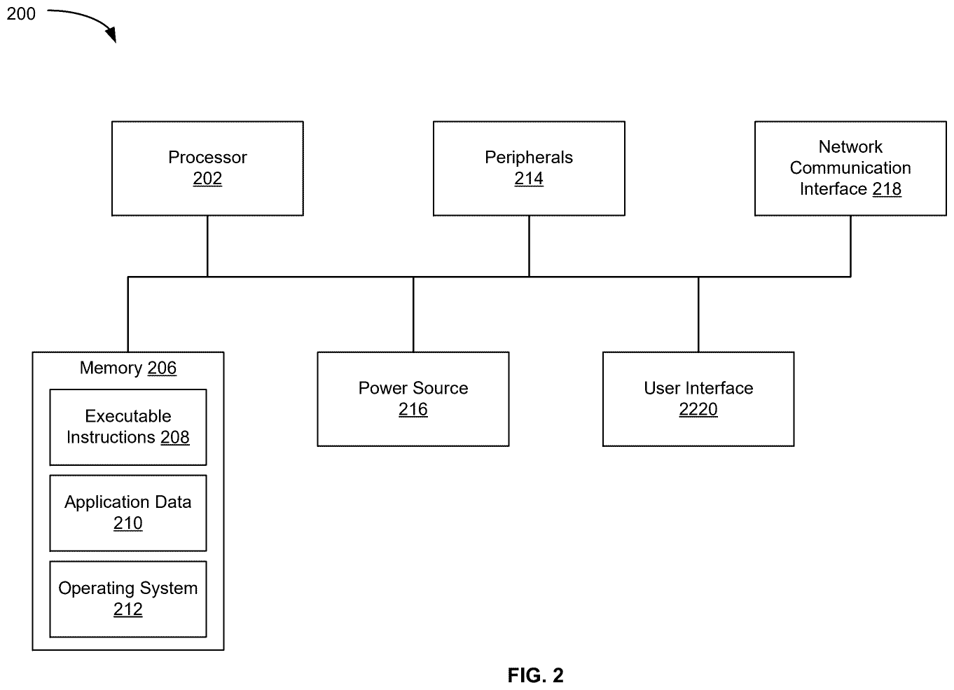

FIG. 2 illustrates an example of computing components of a system 200 for facilitating generation of integrated circuits in accordance with embodiments of the present disclosure. The system 200 can be a computing device or server (or a set of servers providing a cloud computing environment) that may be used to implement the integrated circuit design service infrastructure 110. The computing components can include a processor 202, a bus 204, a memory 206, peripherals 214, a power source 216, a network communication interface 218, a user interface 220, other suitable components, or a combination thereof.

The processor 202 can be a central processing unit (CPU), such as a microprocessor, and can include single or multiple processors having single or multiple processing cores. Alternatively, the processor 202 can include another type of device, or multiple devices, now existing or hereafter developed, capable of manipulating or processing information. For example, the processor 202 can include multiple processors interconnected in any manner, including hardwired or networked, including wirelessly networked. In an example, the operations of the processor 202 can be distributed across multiple physical devices or units that can be coupled directly or across a local area or other suitable type of network. In an example, the processor 202 can include a cache, or cache memory, for local storage of operating data or instructions.

The memory 206 can include volatile memory, non-volatile memory, or a combination thereof. For example, the memory 206 can include volatile memory, such as one or more dynamic random access memory (DRAM) modules such as double data rate (DDR) synchronous DRAM (SDRAM), and non-volatile memory, such as a disk drive, a solid-state drive, flash memory, Phase-Change Memory (PCM), or any form of non-volatile memory capable of persistent electronic information storage, such as in the absence of an active power supply. The memory 206 can include another type of device, or multiple devices, now existing or hereafter developed, capable of storing data or instructions for processing by the processor 202. The processor 202 can access or manipulate data in the memory 206 via the bus 204. Although shown as a single block in FIG. 2, the memory 206 can be implemented as multiple units. For example, a system 200 can include volatile memory, such as random access memory (RAM), and persistent memory, such as a hard drive or other storage.

The memory 206 can include executable instructions 208, data, such as application data 210, an operating system 212, or a combination thereof, for immediate access by the processor 202. The executable instructions 208 can include, for example, one or more application programs, which can be loaded or copied, in whole or in part, from non-volatile memory to volatile memory to be executed by the processor 202. The executable instructions 208 can be organized into programmable modules or algorithms, functional programs, codes, code segments, or combinations thereof to perform various functions described herein. For example, the executable instructions 208 can include instructions executable by the processor 202 to cause the system 200 to automatically, in response to a command, generate an integrated circuit design and associated test results based on a design parameters data structure. The application data 210 can include, for example, user files, database catalogs or dictionaries, configuration information or functional programs, such as a web browser, a web server, a database server, or a combination thereof. The operating system 212 can be, for example, Microsoft Windows®, macOS®, or Linux®; an operating system for a small device, such as a smartphone or tablet device; or an operating system for a large device, such as a mainframe computer. The memory 206 can comprise one or more devices and can utilize one or more types of storage, such as solid-state or magnetic storage.

The peripherals 214 can be coupled to the processor 202 via the bus 204. The peripherals 214 can be sensors or detectors, or devices containing any number of sensors or detectors, which can monitor the system 200 itself or the environment around the system 200. For example, a system 200 can contain a temperature sensor for measuring temperatures of components of the system 200, such as the processor 202. Other sensors or detectors can be used with the system 200, as can be contemplated. In an example, the power source 216 can be a battery, and the system 200 can operate independently of an external power distribution system. Any of the components of the system 200, such as the peripherals 214 or the power source 216, can communicate with the processor 202 via the bus 204.

The network communication interface 218 can also be coupled to the processor 202 via the bus 204. In an example, the network communication interface 218 can comprise one or more transceivers. The network communication interface 218 can, for example, provide a connection or link to a network, such as the network 106 shown in FIG. 1, via a network interface, which can be a wired network interface, such as Ethernet, or a wireless network interface. For example, the system 200 can communicate with other devices via the network communication interface 218 and the network interface using one or more network protocols, such as Ethernet, transmission control protocol (TCP), Internet protocol (IP), power line communication (PLC), Wi-Fi, infrared, general packet radio service (GPRS), global system for mobile communications (GSM), code division multiple access (CDMA), or other suitable protocols.

A user interface 220 can include a display; a positional input device, such as a mouse, touchpad, touchscreen, or the like; a keyboard; or other suitable human or machine interface devices. The user interface 220 can be coupled to the processor 202 via the bus 204. Other interface devices that permit a user to program or otherwise use the system 200 can be provided in addition to or as an alternative to a display. In an example, the user interface 220 can include a display, which can be a liquid crystal display (LCD), a cathode-ray tube (CRT), a light emitting diode (LED) display (e.g., an organic light emitting diode (OLED) display), or other suitable display. In an example, a client or server can omit the peripherals 214. The operations of the processor 202 can be distributed across multiple clients or servers, which can be coupled directly or across a local area or other suitable type of network. The memory 206 can be distributed across multiple clients or servers, such as network-based memory or memory in multiple clients or servers performing the operations of clients or servers. Although depicted here as a single bus, the bus 204 can be composed of multiple buses, which can be connected to one another through various bridges, controllers, or adapters.

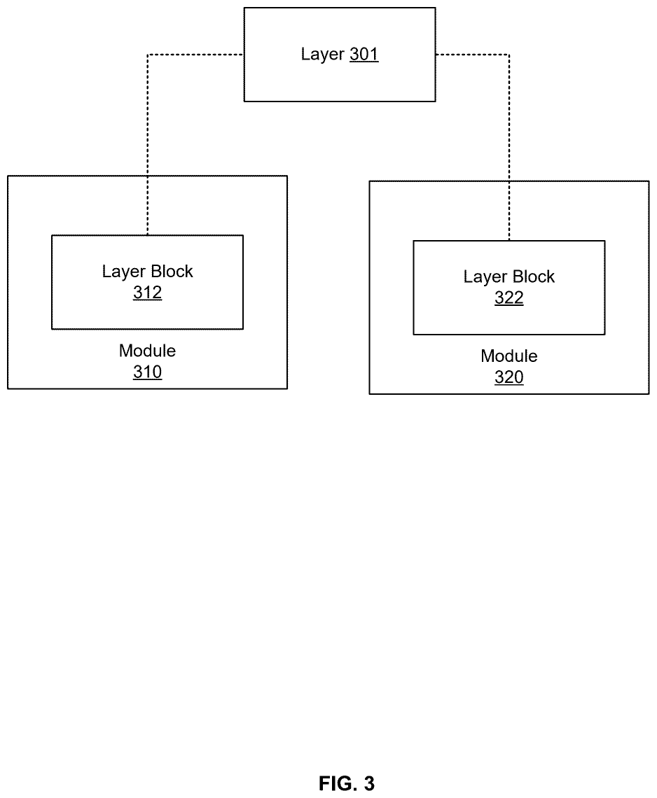

FIG. 3 illustrates an example of components of an integrated circuit design with a layer defined in an HDL in accordance with embodiments of the present disclosure. The integrated circuit design can be defined using an integrated circuit generator, such as any of the generators described herein above including the one described in FIG. 1 (e.g., as part of the integrated circuit design service infrastructure 110). The integrated circuit design includes two modules: a first module 310 and a second module 320. Each of these two modules 310 and 320 correspond to components of an integrated circuit. A layer 301 can be defined for a function to be performed on the integrated circuit design. First aspects (e.g., one or more operations corresponding to a set of instructions) of the function can be implemented by a first layer block 312. Second aspects (e.g., the same or different operation(s)) of the function can be implemented by a second layer block 322. As shown in FIG. 3, code of the first layer block 312 can be included in the code of the first module 310. The code of the first layer block 312 can reference the layer 301. For instance, the instructions of the first layer block 312 are written within a container included in the code of the first module 310. The instructions reference the layer 301. Similarly, code of the second layer block 322 can be included in the code of the second module 320.

In the interest of clarity, consider the following example for the integrated circuit and the layer 301. The integrated circuit includes two input registers that store data, an adder that add bits (e.g., by performing an AND operation) from the two input registers, and an output register that stores the output of the adder. The circuit design may also be protected by implementing a particular type of protection (e.g., single error correction double error detection codes (SECDED), error correction codes, etc.). The layer 301 is a verification layer that verifies the design of the integrated circuit. One example verification function includes verifying that the protection is properly implemented.

In this illustrative example, the first module 310 represents an HDL definition of the two input registers, the adder, and the relevant protection. The second module 320 represents an HDL definition of the output register and the relevant protection. The layer 301 is declared in HDL as a verification layer. A first set of assertions is included, as the code of the first layer block 312, in the code of the first module 310 and references the verification layer. These assertions can check that the data stored in the data input registers includes data to check the protection (e.g., a protection flag, parity bits, etc.) and that the output of the adder is also protected. A second set of assertions is included, as the code of the second layer block 322, in the code of the second module 320 and references the verification layer. These assertions can check that the input data to the output register is protected, and that the data stored in the output register includes protection data (e.g., a protection flag, parity bits, etc.). As such, both layer blocks 312 and 322 can verify the end-to-end protection in the design of the integrated circuit. The verification may involve the output of the adder which is also the input to the output register and, thus, may necessitate a data flow between the two modules 310 and 320. As further described herein below, this data flow can be captured by using ports, which can also be referred to as “coloring.”

Although FIG. 3 shows two modules, a different number of modules may be possible. For instance, a single module may be defined, or more than two modules may be defined. Similarly, although FIG. 3 describes two layer blocks for a layer, a different number of layer blocks may be possible. For instance, a single layer block may be defined, or more than two layer blocks may be defined. In the case where multiple modules may exist, not all modules need to include layer blocks. Furthermore, the layer blocks are herein described as being included in modules. However, the embodiments are not limited as such and similarly and equivalently apply to including one or more layer blocks in one or more libraries (in addition or alternative to including one or more layer blocks in one or more Modules). Additionally, although a particular circuit design is described, the embodiments of the present disclosure are not limited to only the disclosed circuit design. Instead, the embodiments similarly and equivalently apply to other integrated circuit designs.

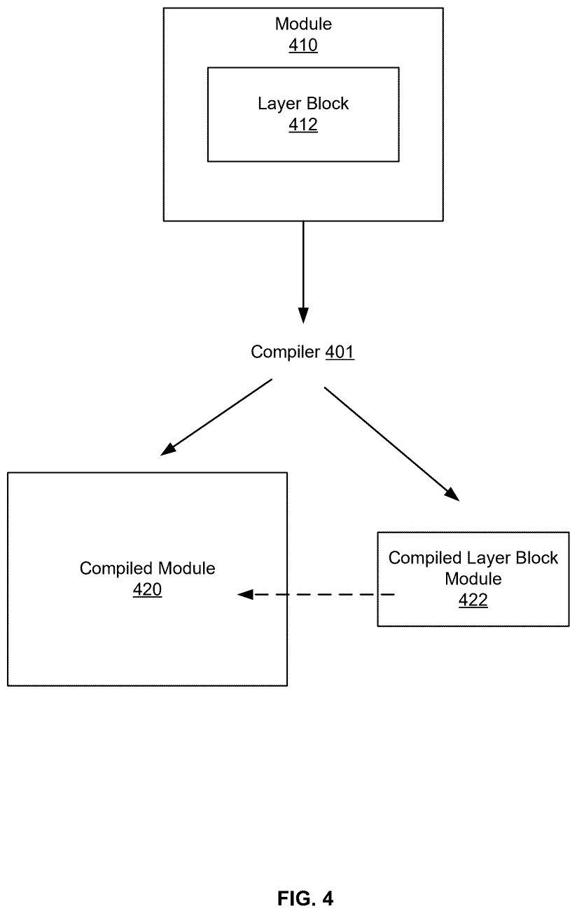

FIG. 4 illustrates an example of components of an integrated circuit design with a layer defined in an RTL data structure in accordance with embodiments of the present disclosure. The components herein are referred to herein as compiled modules and can result from a compilation of an HDL integrated circuit design that includes a module 410 (e.g., similar to the module 310 of FIG. 3) that, in turn, includes a layer block 412 of the layer (e.g., similar to the layer block 312 of FIG. 3).

In an example, the module 410 represents an HDL definition of a hardware component of an integrated circuit, similar to the first module 310 of FIG. 3. The layer block 412 represents assertions for aspects of the layer's function (e.g., particular verification assertions), similar to the layer block 312 of FIG. 3. A compiler 401 (e.g. one included in an integrated circuit generator such as any of the generators described herein above) can compile the HDL definition of the hardware component into an RTL data structure. The result of the compilation includes a compiled module 420 that corresponds to the module 410 and that represents an RTL definition of the hardware component. The compiler 401 can also compile the layer block 412 into a compiled layer block module 422 that represents an RTL definition of the aspects of the layer's function.

In the HDL integrated circuit design, the module 410 includes the layer block 412. In comparison, in the RTL integrated circuit design, the compiled module 420 and the compiled layer block module 422 are separate from each other (e.g., are two separate modules). User input can be received (e.g., to the integrated circuit design service infrastructure 110 of FIG. 1) and can indicate that the layer is to be enabled. In this case, the compiled layer block module 422 can be added to the compiled module 420 (e.g., instantiated therein). User input can also be received and can indicate that the layer is to be disabled. In this case, the compiled layer block module 422 can be removed from the compiled module 420 (e.g., its instantiation is terminated). For instance, in Verilog, a “bind” construct can be used for the instantiation and/or termination. Both cases of enabling and disabling the compiled layer block module 422 are shown with a dashed arrow in FIG. 4. In both cases, the compiled module 420 (e.g., its RTL data structure) need not be modified. Particularly, no ports need to be defined for use in association with the layer being enabled or disabled. The use of ports or coloring is further described in the next figures.

To illustrate, refer back to the example of FIG. 3 with a verification layer and a protected integrated circuit design. Assume that that the module 410 and the layer block 412 are the first module 310 and the first layer block 312, respectively, of FIG. 3. In FIG. 4, the compiled module 420 is an RTL module defining the two input registers and the adder. Further, the compiled layer block module 422 is an RTL module defining the assertions to check the data protection of the input registers and the adder. When the layer is enabled, the assertions can be executed to check the protection of the input registers and adder. When the layer is disabled, no assertions are executed. In both cases, input and output ports of compiled module 420 remain unmodified.

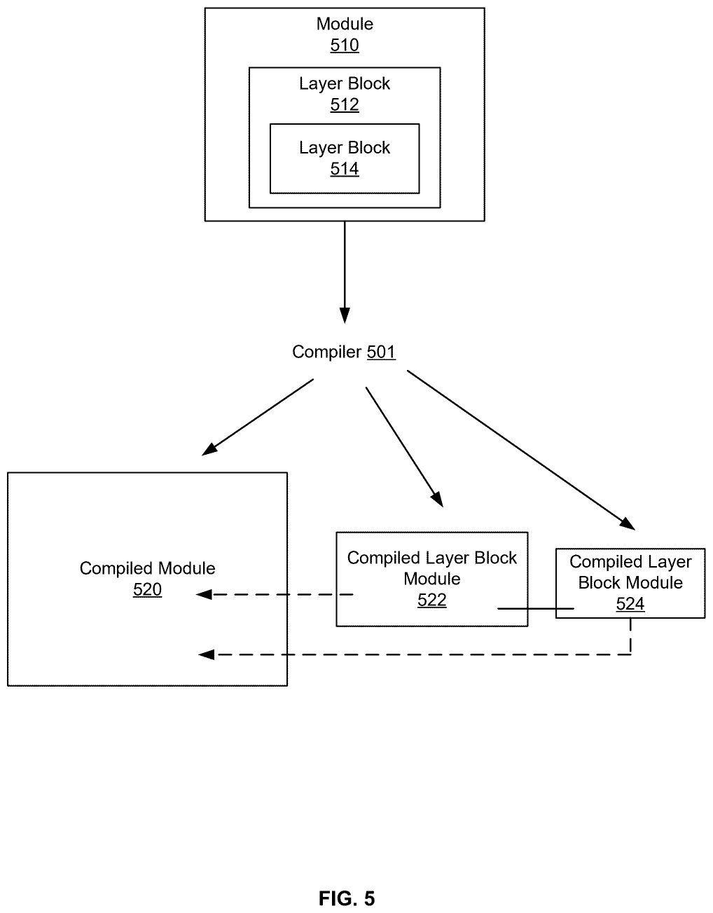

FIG. 5 illustrates another example of components of an integrated circuit design with nested layers defined in an HDL and an RTL data structure in accordance with embodiments of the present disclosure. In comparison to FIG. 4, FIG. 5 shows that layers can be nested. For example, a first layer for a first function can be defined (e.g., a verification layer). A second layer for a second function can also be defined (e.g., a data collection layer). The second layer can be nested in the first layer. In other words, the first layer can be used on its own (e.g., to only verify). Or the first layer and the second layer can be used concurrently (e.g., to collect data and perform verification). But the second layer cannot be used on its own. As such, user input can enable the first layer or the first layer and the second layer but cannot enable the second layer only.

As illustrated, a compiler 501 (e.g. one included in an integrated circuit generator such as any of the generators described herein above) can compile an HDL integrated circuit design into an RTL integrated circuit design. The HDL integrated circuit design includes a module 510 that represents a hardware component (e.g., similar to the module 310 of FIG. 3) and that, in turn, includes a first layer block 512 of the first layer (e.g., similar to the layer block 312 of FIG. 3), where the first layer block 512 nests a second layer block 514 of the second layer. For instance, code of the second layer block 514 references the second layer and is included in code of the first layer block 512. In turn, the code of the first layer block 512 references the first layer and is included in code of the module 510.

In comparison, the RTL integrated circuit design includes a compiled module 520 that corresponds to the module 510 and that represents an RTL definition of the hardware component. The compiler 501 can also compile the first layer block 512 into a first compiled layer block module 522 that represents an RTL definition of the aspects of the first layer's function. Further, the compiler 501 can compile the second layer block 515 into a second compiled layer block module 524 that represents an RTL definition of the aspects of the second layer's function. The compiler 501 can define dependencies between the two compiled layer block modules 522 and 524 given that the second layer is nested in the first layer. This dependency is illustrated in FIG. 5 with a solid line. In an example, each or both two compiled layer block modules 522 and 524 can reference the layer of the other compiled layer block module 522 or 524 and/or the other compiled layer block module 522 or 524 to define the dependency. For instance, the first compiled layer block module 522 can reference the second layer and/or the second compiled layer block module 524. Additionally, or alternatively, the second compiled layer block module 524 can reference the first layer and/or the first compiled layer block module 522. Additionally, or alternatively, each or both two compiled layer block modules 522 and 524 can indicate that its input and/or output are accessible to the other compiled layer block module 522 or 524. For instance, the first compiled layer block module 522 can indicate that its input and/or output are accessible to the second compiled layer block module 524. Additionally, or alternatively, the second compiled layer block module 524 can indicate that its input and/or output are accessible to the first compiled layer block module 522.

In the HDL integrated circuit design, the module 510 includes the first layer block 512 that, in turn, includes the second layer block 514. In comparison, in the RTL integrated circuit design, the compiled module 520, the first compiled layer block module 522, and the second compiled layer block module 524 are separate from each other (e.g., are three separate modules). User input can be received (e.g., to the integrated circuit design service infrastructure 110 of FIG. 1) and can indicate that the first layer only is to be enabled. In this case, the first compiled layer block module 522 can be added to the compiled module 520 (e.g., instantiated therein). User input can also be received indication that the first layer and the second layer are to be enabled. In this case, the first compiled layer block module 522 can be added to the compiled module 520 (e.g., instantiated therein). The second compiled layer block module 524 can also be added to the compiled module 520 (e.g., instantiated therein, instead of being instantiated in the instantiated module corresponding to the first layer block). Given the dependency between the two compiled layer block modules, input and/or output of the first instantiated module corresponding to the first layer block can be accessible to the second instantiated module corresponding to the second layer block and/or vice versa.

User input can also be received and can indicate that the first layer is to be disabled. In this case, the first compiled layer block module 522 can be removed from the compiled module 520 (e.g., its instantiation is terminated). If the second layer was enabled, here also the second layer can be automatically disabled (e.g., without additional user input) by removed the second compiled layer block module 524 from the compiled module 520 (e.g., its instantiation is terminated). Alternatively, when both layers are enabled, user input can be received to disable the second layer only. In this case, only the second compiled layer block module 524 can be removed from the compiled module 520 (e.g., its instantiation is terminated).

In the above examples of layer enablement and disablement, in Verilog, a “bind” construct can be used for the instantiation and/or termination of a compiled layer block module within the compiled module 510. Both cases of enabling and disabling the layers are shown with dashed arrows in FIG. 5. In both cases, the compiled module 520 (e.g., its RTL data structure) need not be modified. Particularly, no ports need to be defined for use in association with any of the layers being enabled or disabled. The use of ports or coloring is further described in the next figures.

Although FIG. 5 illustrates a nested hierarchy of two layers, the embodiments of the present disclosure are not limited as such. Instead, the embodiments similarly and equivalently apply to any nesting hierarchy. For example, the nested hierarchy can correspond to a layer at one level of the hierarchy nesting multiple layers at the next level of the hierarchy and/or nesting multiple layers in multiple lower levels of the hierarchy.

Regardless, the compilation results in compiled layer block modules that are separate from each other and from the compiled module of the underlying hardware component. The compilation also results in the dependency definition between the compiled layer block modules depending on the hierarchy.

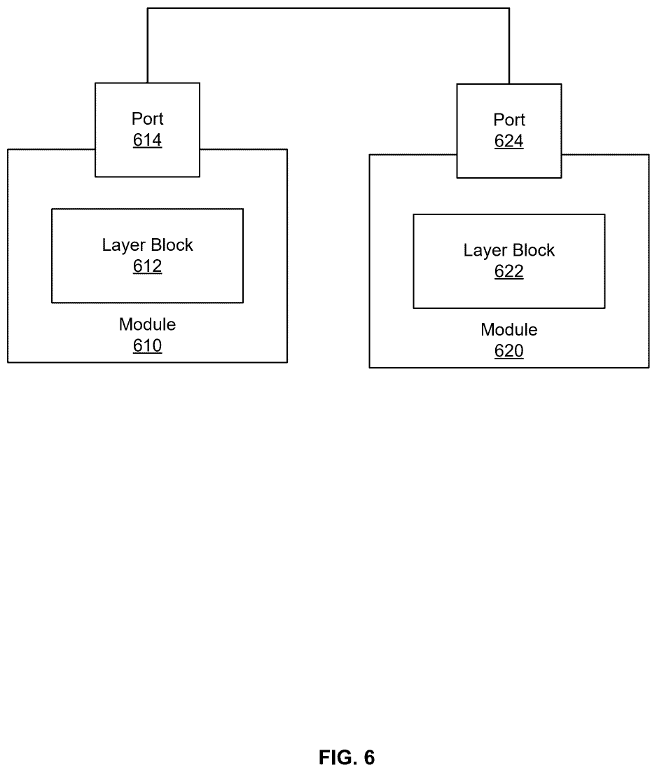

FIG. 6 illustrates an example of data flow between components of an integrated circuit design defined in an HDL in accordance with embodiments of the present disclosure. The HDL integrated circuit design is similar to that of FIG. 3, except that the port definition is shown herein. In the interest of brevity, the similarities are not repeated herein. Instead, the description of FIG. 3 applies to FIG. 6 also. Particularly, the HDL integrated circuit design includes a first module 610, a second module 620, a first layer block 612 of a layer, and a second layer block 622 of the layer, similar to the first module 310, the second module 320, the first layer block 312, and the second layer block module 322, respectively, of FIG. 3. The first module 610 includes the first layer block 612. Similarly, the second module 620 includes the second layer block 622.

To enable data flow from one layer block 612 or 622 to the other layer block 622 or 612 (e.g., a unidirectional flow) and/or between the layer blocks 612 and 622 (e.g., a bidirectional flow), a first port 614 for the first module 610 can be defined and a second port 624 for the second module 620 can be defined. A port generally represents that input and/or output of a layer block of a layer is accessible if the layer is enabled. In Chisel, the port can be of a “probe”type and can reference the layer and/or one or more layer blocks.

In the illustration of FIG. 6 and referring back to the illustrative use case of a verification layer for a protected integrated circuit design, the first port 614 can reference the verification layer and can indicate that the output of the first layer block 612 is accessible to the second layer block 622. In comparison, the second port 624 can reference the verification layer and can indicate that the output of the first layer block 612 can be input to the second layer block 622.

Although FIG. 6 illustrates two modules each including a layer block of a same block, the embodiments of the present disclosure are not limited as such. For instance, more than two modules can exist, each including one or more layer blocks of a layer. Here, a port can be defined for each layer block and can be included (e.g., as code) in the module that includes the layer block. In another illustration, multiple layers can be nested (as in FIG. 5). As such, a module can include multiple nested layer blocks. Here also, a port can be defined for each layer block of the nested layer blocks and can be included (e.g., as code) in the module.

As further described in the next figure, upon compilation, the ports 610 and 620 can be removed. In other words, the compiled module corresponding to the first module 610 does not include a port specific to the layer. Likewise, the compiled module corresponding to the second module 620 does not include a port specific to the layer. Instead, one or more references can be made in one or more compiled modules to enable the data flow when the layer is enabled and disable the data flow when the layer is disabled. In Verilog, such references can take the form of hierarchical names.

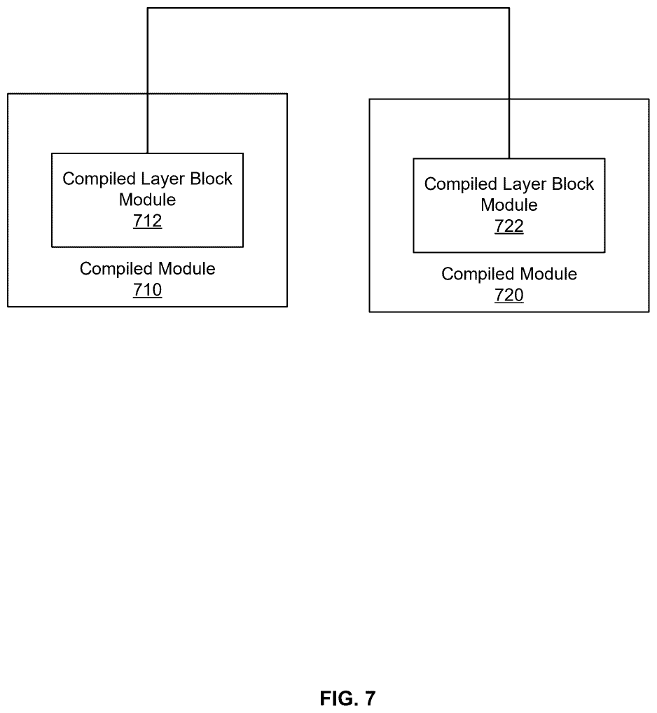

FIG. 7 illustrates an example of data flow between components of an integrated circuit design defined in an RTL data structure in accordance with embodiments of the present disclosure. The components represent compiled modules of the components of the HDL integrated circuit design of FIG. 6. The compilation can be performed by any of the compilers described herein above.

As illustrated, the components include a first compiled module 710 corresponding to the first module 610, a second compiled module 720 corresponding to the second module 620, a first compiled layer block module 712 corresponding to the first layer block module 612, and a second compiled layer block module 722 corresponding to the second layer block 622. In FIG. 7, the first compiled layer block module 712 and the second compiled layer block module 722 are shown as added (e.g., instantiated) to the first compiled module 710 and the second compiled module 720, respectively, upon the layer being enabled. Nonetheless, as described herein above, the RTL definitions of these modules 710, 712, 720, and 722 are separate from each other.

Although the HDL integrated circuit design includes the ports 614 and 624, the RTL integrated circuit design does not include corresponding ports. In particular, the compiler removes the ports 614 and 624 and can replace with one or more references for data paths between the first compiled layer block module 712 and the second compiled layer block module 722, where these two data paths are enabled when the layer is enabled (and, thus, these two modules instantiated) and disabled when the layer is disabled (and, thus, the instantiation of the two modules is terminated). For instance, referring to the above illustrative case of a verification layer, the first compiled layer block module 712 can include a hierarchical name of the second compiled layer block module 722 to indicate that the output of the first compiled layer block module 712 is accessible to the second compiled layer block module 722 when the layer is enabled. The data path between the two compiled layer block modules 712 and 722 (upon instantiation due to the layer being enabled) can use port of the compiled modules 710 and 722 where these ports are part of the design of the underlying hardware components rather than being specific to the layer.

Although FIG. 7 illustrates two compiled modules and two compiled layer block modules that can be added and removed to the compiled modules upon a layer being enabled or disabled, the embodiments are not limited as such. For instance, more than two compiled modules, more than one layer, and/or more than one compiled layer block modules can be implemented. In such cases, any port defined for a layer in HDL can be removed in the RTL data structure and, instead, references (e.g., hierarchical names) can be used.

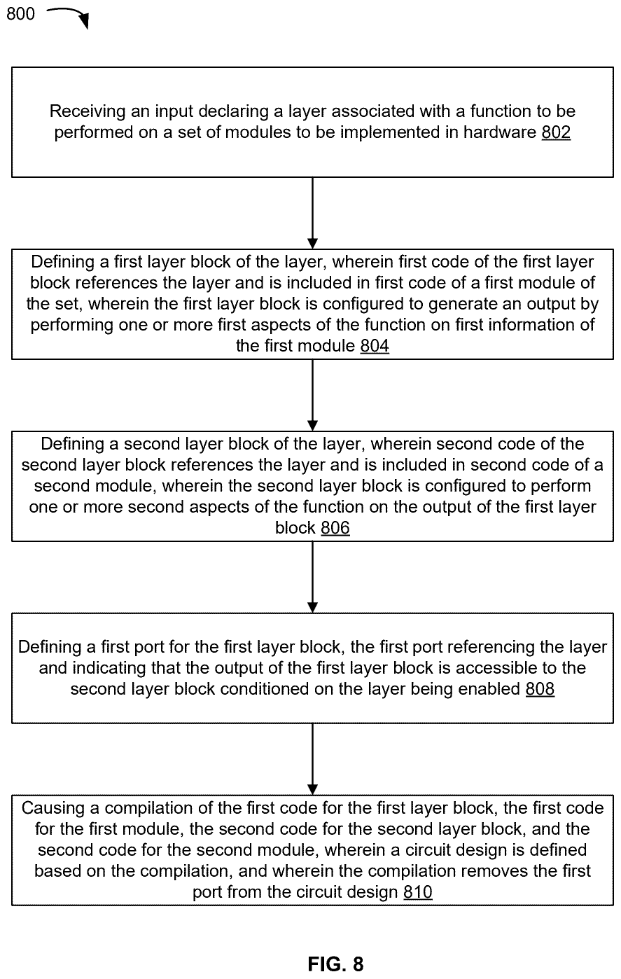

FIG. 8 illustrates an example of a flow 800 for generating an integrated circuit design with one or more layers in accordance with embodiments of the present disclosure. Operations of the flow can be implemented by a system that implements components of an integrated circuit design service infrastructure, such as the system 200 of FIG. 2. In some examples, the operations may be implemented by executing instructions stored in a tangible, non-transitory, computer-readable storage medium, such as a memory of the system. While the flows are described in a specific sequence, it should be understood that the present disclosure contemplates that the operations may be performed in different sequences than the sequence illustrated, and certain described operations may be omitted or not performed altogether.

In an example, the flow 800 includes operation 802, where the system receives an input declaring a layer associated with a function to be performed on a set of modules to be implemented in hardware. For example, the input may be received via a user interface and may define the type of the layer and the function the layer supports.

In an example, the flow 800 includes operation 804, where the system defines a first layer block of the layer, wherein first code of the first layer block references the layer and is included in first code of a first module of the set, wherein the first layer block is configured to generate an output by performing one or more first aspects of the function on first information of the first module. For instance, the first layer block can be defined in HDL as a set of assertions added to the code of the first module and can reference the layer.

In an example, the flow 800 includes operation 806, where the system defines a second layer block of the layer, wherein second code of the second layer block references the layer and is included in second code of a second module, wherein the second layer block is configured to perform one or more second aspects of the function on the output of the first layer block. For instance, the second layer block can be defined in HDL as a set of assertions added to the code of the second module and can reference the layer.

In an example, the flow 800 includes operation 808, where the system defines a first port for the first layer block, the first port referencing the layer and indicating that the output of the first layer block is accessible to the second layer block conditioned on the layer being enabled. For instance, the first port can be a probe type that references the layer and can indicate that input to the first layer block from the second layer block and/or output of the first layer block to the second layer block is allowed conditioned on the layer is enabled.

In an example, the flow 800 includes operation 808, where the system causes a compilation of the first code for the first layer block, the first code for the first module, the second code for the second layer block, and the second code for the second module, wherein a circuit design is defined based on the compilation, and wherein the compilation removes the first port from the circuit design. For instance, a compiler generates these modules as compiled modules that are separate from each other. The compiler can also remove the first port and can replace this port with a reference (e.g., a hierarchical name) in one or more compiled layer block modules.

Although the embodiments above have been described in considerable detail, numerous variations and modifications will become apparent to those skilled in the art once the above disclosure is fully appreciated. It is intended that the following claims be interpreted to embrace all such variations and modifications.

The specification and drawings are to be regarded in an illustrative rather than a restrictive sense. Various modifications and changes may be made without departing from the spirit and scope of the disclosure as set forth in the claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

Disjunctive language such as the phrase “at least one of X, Y, or Z,” unless specifically stated otherwise, is intended to be understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

What is claimed is:

1. A method comprising:
receiving an input declaring a layer associated with a function to be performed on a set of modules to be implemented in hardware;
defining a first layer block of the layer, wherein first code of the first layer block references the layer and is included in first code of a first module of the set, wherein the first layer block is configured to generate an output by performing one or more first aspects of the function on first information of the first module;
defining a second layer block of the layer, wherein second code of the second layer block references the layer and is included in second code of a second module, wherein the second layer block is configured to perform one or more second aspects of the function on the output of the first layer block;
defining a first port for the first layer block, the first port referencing the layer and indicating that the output of the first layer block is accessible to the second layer block conditioned on the layer being enabled; and
causing a compilation of the first code for the first layer block, the first code for the first module, the second code for the second layer block, and the second code for the second module, wherein a circuit design is defined based on the compilation, and wherein the compilation removes the first port from the circuit design.

2. The method of claim 1, wherein the first port represents a data flow indicating that the output can be sent from the first layer block to the second layer block conditioned on the layer being enabled.

3. The method of claim 1, wherein the first port is removed, upon the compilation, from a compiled version of the first layer block and a compiled version of the first module.

4. The method of claim 3, wherein the first port is replaced in the compiled version of the first layer block with a reference to at least the second layer block.

5. The method of claim 1, wherein the layer is enabled after the compilation, and wherein ports of a compiled version of the first module remain unchanged upon enabling the layer after the compilation.

6. The method of claim 5, wherein the enabling the layer after the compilation comprises including a compiled version of the first layer block in the compiled version of the first module, wherein the compiled version of the first layer block includes a reference to the second layer block, and wherein the first port after the compilation.

7. The method of claim 1, wherein the compilation includes generating a first compiled version of the first layer block that is separate from a first compiled version of the first module.

8. The method of claim 7, wherein the compilation further includes generating a second compiled version of the second layer block that is separate from the first compiled version of the first module, the first compiled version of the first layer block, and a second compiled version of the second layer block.

9. The method of claim 8, wherein the layer is enabled after the compilation, and wherein enabling the layer comprises including the first compiled version of the first layer block in the first compiled version of the first module, the second compiled version of the second layer block in the second compiled version of the second module.

10. The method of claim 9, wherein the second compiled version of the second layer block includes a reference to the first layer block, wherein the reference enables data to flow from the first compiled version of the first layer block to the second compiled version of the second layer block.

11. The method of claim 1, further comprising:
defining a second port for the second layer block, the second port referencing the layer and indicating that the output of the first layer block is accessible to the second layer block conditioned on the layer being enabled.

12. The method of claim 1, wherein the layer is a first layer, and wherein the method further comprises:
defining a third layer block of a second layer, wherein third code of the third layer block references the layer and is included in the first code of the first layer block.

13. The method of claim 12, wherein the compilation generates a compiled version of third layer block that is separate from a compiled version of the first layer block and a compiled version of the first module.

14. The method of claim 13, wherein the compiled version of the first layer block references the compiled version of the third layer block.

15. The method of claim 13, wherein the compiled version of the third layer block references the compiled version of the first layer block.

16. The method of claim 12, wherein the second layer is enabled after the compilation upon the first layer being enabled.

17. The method of claim 12, wherein the first layer is enabled after the compilation, wherein enabling the first layer excludes enabling the second layer.

18. The method of claim 12, wherein the compilation generates a set of ports for the first module based on the first code of the first module and excludes a port corresponding to the first port.

19. One or more non-transitory computer-readable storage media storing instructions that, upon execution on a computer system, cause the computer system to perform operations comprising:
receiving an input declaring a layer associated with a function to be performed on a set of modules to be implemented in hardware;
defining a first layer block of the layer, wherein first code of the first layer block references the layer and is included in first code of a first module of the set, wherein the first layer block is configured to generate an output by performing one or more first aspects of the function on first information of the first module;
defining a second layer block of the layer, wherein second code of the second layer block references the layer and is included in second code of a second module, wherein the second layer block is configured to perform one or more second aspects of the function on the output of the first layer block;
defining a first port for the first layer block, the first port referencing the layer and indicating that the output of the first layer block is accessible to the second layer block conditioned on the layer being enabled; and
causing a compilation of the first code for the first layer block, the first code for the first module, the second code for the second layer block, and the second code for the second module, wherein a circuit design is defined based on the compilation, and wherein the compilation removes the first port from the circuit design.

20. A computer system comprising:
one or more processors; and
one or more memories storing instructions that, upon execution by the one or more processors, configure the computer system to:
receive an input declaring a layer associated with a function to be performed on a set of modules to be implemented in hardware;
define a first layer block of the layer, wherein first code of the first layer block references the layer and is included in first code of a first module of the set, wherein the first layer block is configured to generate an output by performing one or more first aspects of the function on first information of the first module;
define a second layer block of the layer, wherein second code of the second layer block references the layer and is included in second code of a second module, wherein the second layer block is configured to perform one or more second aspects of the function on the output of the first layer block;
define a first port for the first layer block, the first port referencing the layer and indicating that the output of the first layer block is accessible to the second layer block conditioned on the layer being enabled; and
cause a compilation of the first code for the first layer block, the first code for the first module, the second code for the second layer block, and the second code for the second module, wherein a circuit design is defined based on the compilation, and wherein the compilation removes the first port from the circuit design.
